(19) United States
(12) Patent Application Publication
(10) Pub. No.: US 2010/0155935 A1
(43) Pub. Date: Jun. 24, 2010

(54) Protective coating for semiconductor substrates

(75) Inventors: Ed Prack, Phoenix, AZ (US); Leonel Arana, Phoenix, AZ (US); Sandeep Razdan, Chandler, AZ (US)

Correspondence Address: INTEL CORPORATION;c/o CPA Global, P.O. BOX 52050, MINNEAPOLIS, MN, 55402, US

(73) Assignee: Intel Corporation

(21) Appl. No.: 12/317,447

(22) Filed: Dec. 23, 2008

(51) Int. Cl. H01L 23/10; H01L 21/00

(52) U.S. Cl. 257/729; 438/465; 257/E21.002; 257/E23.194

(57) ABSTRACT

Methods for coating a protective material on a semiconductor substrate to protect a back surface thereof from defects are provided, by depositing a diamond-like coating (DLC) material thereon at a low temperature, e.g. between about 150° C. to about 350° C.

### BACKGROUND

1. Technical Field

Embodiments of the invention relate to methods for coating a semiconductor substrate with a protective material to increase the mechanical strength and scratch resistance of the semiconductor substrate.

2. Description of Related Art

Semiconductor packages, especially packages which involve thin core or coreless substrate technologies, are prone to die defects on a back surface of a semiconductor die. In many instances, die defects may originate as scratches and dents introduced during assembly and test processes. Subsequently during reliability testing, these scratches and dents may develop into die cracks. Current practice requires semiconductor packages with cracked dies to be discarded which results in a yield loss. Especially in packages where thin substrate cores are used in combination with a thick semiconductor die, an unacceptably high die yield loss due to die cracks has been observed.

### BRIEF DESCRIPTION OF THE DRAWINGS

Embodiments of the invention are disclosed hereinafter with reference to the drawings, in which:

FIG. 1 shows a wafer prior to depositing a diamond-like carbon (DLC) material thereon;

FIG. 2A shows the wafer of FIG. 1 with a DLC material deposited thereon according to an embodiment of the invention;

FIG. 2B shows a die singulated from the wafer of FIG. 2A according to an embodiment of the invention;

FIG. 3 illustrates an ion beam sputter deposition (IBSD) apparatus suitable for depositing a DLC material;

FIG. 4 illustrates a plasma-assisted chemical vapour deposition (PACVD) apparatus suitable for depositing a DLC material;

FIG. 5 is a flow sequence illustrating deposition of a DLC material using the apparatus of FIG. 3 according to one embodiment of the invention; and

FIG. 6 is a flow sequence illustrating deposition of a DLC material using the apparatus of FIG. 4 according to one embodiment of the invention.

### DETAILED DESCRIPTION

In the following description, numerous specific details are set forth in order to provide a thorough understanding of various illustrative embodiments of the invention. It will be understood, however, to one skilled in the art, that embodiments of the invention may be practiced without some or all of these specific details. In other instances, well known process operations have not been described in detail in order not to unnecessarily obscure pertinent aspects of embodiments being described. In the drawings, like reference numerals refer to same or similar functionalities or features throughout the various presented views.

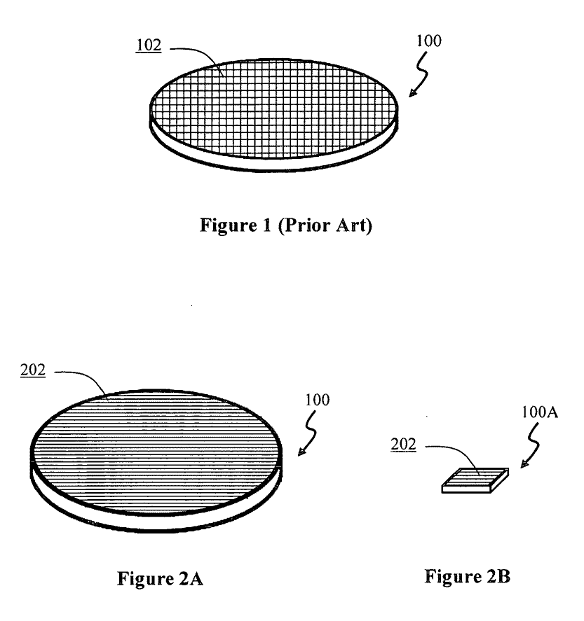

FIG. 1 shows a conventional semiconductor wafer 100 having a bare back surface 102. FIG. 2A shows the wafer 100 of FIG. 1 with a layer of a diamond-like carbon (DLC) material 202 deposited on a back surface 102 of the wafer 100. FIG. 2B shows a semiconductor die 100A singulated from the wafer 100 of FIG. 2A, where a back surface 102 of the die 100A is deposited with a layer of a DLC material 202.

The DLC material 202 suitable for use with embodiments of the invention may have sufficient hardness (e.g. Vickers hardness number of 1,000 to 3,000), low coefficient of friction (e.g. about 0.1), high chemical resistance (or is chemically inert), high thermal conductivity (e.g. 700 W/m.K to 110 W/m.K), high electrical resistivity (e.g. 10⁶ to 10¹² ohm-cm) and, high wear and scratch resistance. These properties are useful to protect a back surface 102 of a wafer 100 or a die 100A from defects by increasing mechanical strength, wear and scratch resistance of the wafer 100 or die 100A without adversely affecting the thermal performance of the final package product. The DLC material 202 may also have a low deposition temperature in order to preserve the integrity (e.g. physical shape and condition) of the wafer 100 or die 100A, and electronic functions of circuitry fabricated on a front surface of the wafer 100 or die 100A. For semiconductor wafers, deposition temperatures may be maintained at up to 350° C. For a semiconductor die mounted on a package substrate, deposition temperatures may be maintained between about 150° C. and about 260° C. depending on duration of the deposition process.

Various methods of depositing a DLC material 202 onto a back surface 102 of a semiconductor substrate (e.g. wafer 100) may be used. For example, ion beam sputter deposition (IBSD) methods may be employed. In another example, plasma-assisted chemical vapour deposition (PACVD) methods may be employed. Although the following paragraphs describe methods using IBSD and PACVD, it is to be appreciated that embodiments of the invention are not limited to these methods; other methods may be applicable with suitable modifications.

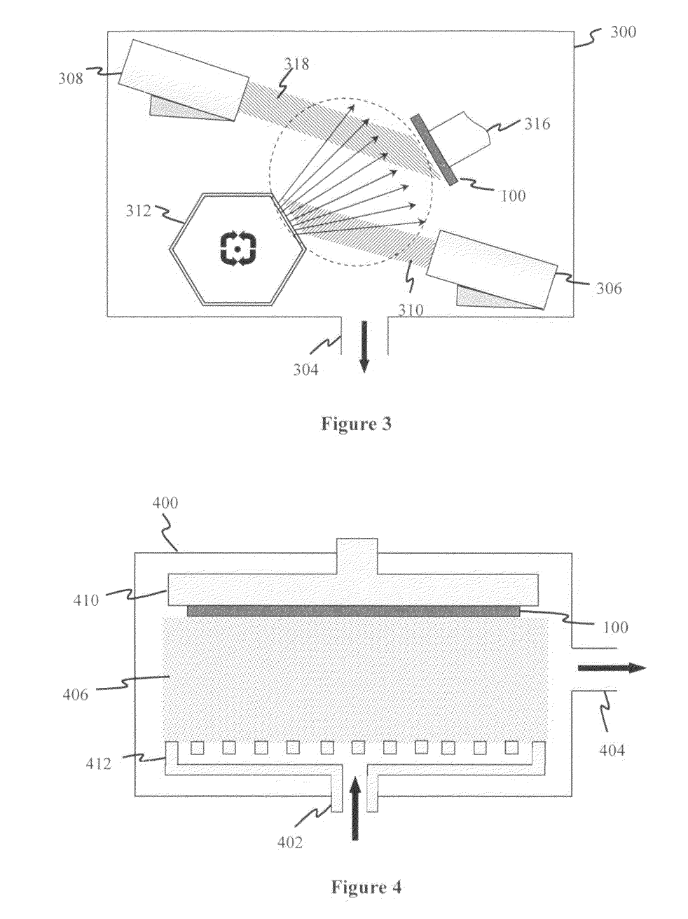

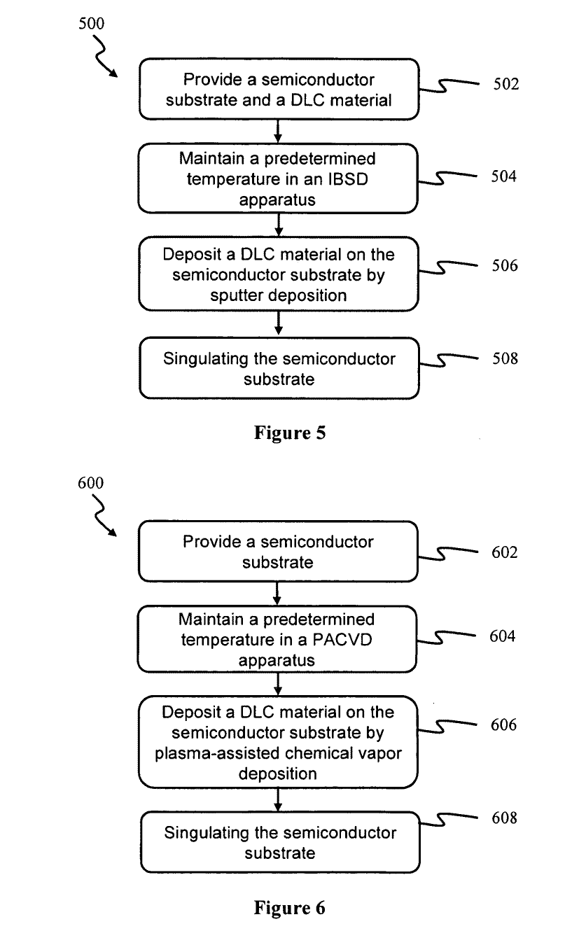

Reference is now made to FIG. 3 illustrating an ion beam sputter deposition (IBSD) apparatus and FIG. 5 illustrating a flow sequence for depositing a DLC material 202 on a back surface 102 of a wafer 100 using the apparatus of FIG. 3.

The ion beam sputter deposition apparatus (hereinafter “IBSD apparatus”) of FIG. 3 allows material deposition on a semiconductor substrate (e.g. wafer 100) in conjunction with the use of ion beams. The IBSD apparatus comprises a process chamber 300 in which a vacuum environment may be formed by drawing air through an outlet 304. In the process chamber 300, a first ion source 306 and a second ion source 308 (or ion assist source, IAD) may be provided. The ion source 306 is to direct an energetic, broad first ion beam 310 at a grounded sputtering target provided on a carousel 312. In one embodiment, the sputtering target may contain amorphous carbon (a-C) or hydrogenated amorphous carbon (a-C:H) which would enable formation of a DLC material coating with strong sp² and sp³ bonds. Multiple copies of a sputtering target may be provided on various surfaces of the carousel 312 which is rotatable in a clockwise direction or an anticlockwise direction or both directions. When one copy of the sputtering target is used up, the carousel 312 may be rotated to switch to an unused copy of sputtering target provided on another surface of the carousel to continue with material deposition. This way, efficiency and output of a deposition process can be increased with minimal interruptions especially when a high volume of wafers 100 is to be processed. In certain embodiments, sputtering targets having different material compositions may be provided on the surfaces of the carousel 312 to deposit multiple thin films of different materials on a wafer 100 if required.

A first ion beam 310 emitted from the first ion source 306 is to energize a sputtering target which is to emit sputtered particles 314 containing a DLC material 202 to be deposited on a wafer 100 appropriately mounted on a substrate holder 316 in a path of the sputtered particles 314. A second ion beam 318 comprising energetic noble or reactive ions and emitted from the second ion source 308 may be directed at the deposited DLC material 202 on the wafer 100 to improve stability, density, dielectric and optical properties of the DLC coating.

In the embodiments of the invention, ion sources 306, 308 of “gridded” and/or “gridless” type may be used depending on required process conditions, maintenance costs, and deposition materials. Additionally, various ion beam sizes may be suitable depending on the size and geometry of the substrate. Further, a neutralizer (not shown) or an electron source may be provided to minimize charging effect of the ion beams 310, 318 on a wafer 100, sputtering targets and surfaces of the process chamber 300.

A flow sequence 500 for depositing a DLC material 202 on a wafer 100 using the IBSD apparatus of FIG. 3 is illustrated as follows with reference to FIG. 5. At least one semiconductor substrate (e.g. wafer 100) is appropriately mounted on a substrate holder 316 such that a back surface 102 of the wafer 100 is designated to be a deposition surface. A DLC material 202 is provided on appropriate surfaces of the carousel 312 as a sputtering target (block 502). A vacuum environment (e.g. about 10⁻⁴ Torr) may then be formed in the process chamber 300 by drawing air out through an outlet 304. Temperature in the process chamber 300 may be adjusted and maintained at a predetermined temperature to facilitate deposition (block 504). Depending on equipment used, quartz lamps may be used for heating and cooling chucks may be used for cooling or maintaining temperature. At the predetermined temperature, deposition of a DLC material 202 may be performed. To this purpose, a first ion beam 310 from a sputter deposition ion source 306 is continuously fired at a sputtering target provided on the carousel 312 to emit sputter particles containing a DLC material 202 to be deposited on a back surface of the wafer 100 (block 506). The back surface 102 of the wafer 100 may be exposed to the sputter particles for a predetermined period time to obtain a desired thickness (e.g. about 25 Angstroms) of the DLC material 202 on the wafer 100. If required, a position of the wafer 100 relative to the carousel 312 may be adjusted as and when required to ensure uniform deposition. Additionally, a second ion beam 318 containing noble or reactive ions from the ion assist source (IAD) 308 may be directed at the wafer 100 during the deposition process to improve structural and growth quality of the deposited DLC material 202. The wafer 100 with a layer of the DLC material 202 deposited thereon may then be removed from the IBSD apparatus and is subsequently singulated into a plurality of dice which may then be packaged (block 508).

Reference is now made to FIG. 4 illustrating a plasma-assisted chemical vapor deposition apparatus (hereinafter “PACVD apparatus”) and FIG. 6 illustrating a flow sequence for depositing a DLC material 202 on a back surface 102 of a wafer 100 using the apparatus of FIG. 5.

The PACVD apparatus utilizes plasma to enhance chemical reaction rates of precursors containing a DLC material to be deposited on a semiconductor substrate (e.g. wafer 100). The PACVD apparatus comprises a process chamber 400 in which a vacuum environment may be formed. Two openings, namely a gas inlet 402 and an extraction outlet 404, are provided in the process chamber 400. The gas inlet 402 facilitates introduction of reaction gases into the process chamber 400 for creating plasma 406 containing a DLC material 202. Examples of the reaction gases include silane, oxygen, argon, ammonia and nitrogen. A combination of the reaction gases may be used in a PACVD apparatus depending on the material to be deposited. In one embodiment, the reaction gas includes a hydrocarbon-based precursor which enables the deposition of a DLC material 202 on a wafer 100. The extraction outlet 404 allows forming of a vacuum environment by drawing air and/or remnants of plasma 406 from the process chamber 400.

In the process chamber 400, a first electrode 410 and one or more second electrode 412 which is spaced apart from the first electrode 410 are provided. The first electrode 410 may be coupled to a substrate holder. A radio frequency (RF) signal may be applied to the first electrode 410 and the second electrodes 412 to generate an electric field therebetween. The electric field is to discharge a reaction gas in the process chamber 400 to produce plasma 406 containing a DLC material 202. The discharging may be by capacitive or inductive methods. Alternatively, a direct-current (DC) or alternating-current (AC) may alternatively be used to generate an electric field. Energy from the plasma 406 facilitates chemical reactions required for deposition of a DLC material on the wafer 100.

A flow sequence 600 for depositing a DLC material on a wafer 100 using the PACVD apparatus of FIG. 4 is illustrated as follows with reference to FIG. 6. At least one semiconductor substrate (e.g. wafer 100) is appropriately mounted on a substrate holder which is coupled to a first electrode 410 (block 602). A back surface 102 of the wafer 100 is designated to be a deposition surface and is therefore suitably arranged relative to the second electrodes 412 to allow generation of an electric field therebetween. A vacuum environment is then formed in the process chamber 400 by extraction of air and/or remnants of plasma 406 therefrom. Temperature of the process chamber 400 is adjusted and maintained at a predetermined temperature (block 604). Depending on equipment used, quartz lamps may be used for heating and cooling chucks may be used for cooling or maintaining temperature. A reaction gas, e.g. a hydrocarbon-based precursor, is introduced into the process chamber 400. An appropriate electrical stimulation, e.g. radio frequency (RF) signal, direct-current (DC) or alternating-current (AC), is provided to the first electrode 410 and the second electrodes 412 to generate an electric field therebetween which discharges the reaction gas to produce plasma 406 containing a DLC material 202. The highly energized ionized particles forming the plasma 406 are then deposited on a back surface 102 of the wafer 100 to form a layer of DLC material 202 thereon (block 606). The wafer 100 may be exposed to the plasma 406 for a predetermined time period to achieve a desired thickness of deposited DLC material. The wafer 100 with the DLC material 202 deposited thereon may then be removed from the IBSD apparatus and is subsequently singulated into a plurality of dice which may then be packaged (block 608).

While the foregoing description does not include treating or preparing the semiconductor substrate prior to deposition of a DLC material 202, it is to be appreciated that such pre-treatment may be included in some embodiments if required. Possible pre-treatments includes, but are not limited to, wet-etching or plasma-etching of a back surface of a semiconductor substrate to remove oxide and/or modify surface roughness. Further, it is to be understood that embodiments of the invention are applicable, with suitable modifications, to a semiconductor substrate in various forms, e.g. a wafer (a bare wafer or a wafer mounted on a package substrate) and, one or more dice singulated from a wafer.

FIG. 2B shows a die 100A singulated from a wafer 100 having a DLC material 202 deposited thereon according to an embodiment of the invention. The die 100A contains a thin continuous layer of diamond-like carbon (DLC) material 202 deposited on a back surface 102 of the die 100A. The DLC material 202 may have a thickness of between about 25 Angstroms or other suitable values depending on requirements of applications.

The thin layer of DLC material 202 is to protect a back surface 102 of a die 100A from defects, such as scratches and cracks. With the protection provided by a DLC material 202, improved mechanical strength and wear and scratch resistance are achieved in the die 100A and a semiconductor package containing the die 100A. This would greatly reduce die defects and die crack issues which may arise during assembly operations, and therefore improving yield. Because a DLC material 202 has high thermal conductivity and low junction temperature, coating a DLC material 202 on a wafer 100 or a die 100A would not adversely affect the thermal performance of the coated wafer or die.

Other embodiments will be apparent to those skilled in the art from consideration of the specification and practice of the invention. Furthermore, certain terminology has been used for the purposes of descriptive clarity, and not to limit the disclosed embodiments of the invention. The embodiments and features described above should be considered exemplary, with the invention being defined by the appended claims.

1. A method comprising:
depositing a diamond-like carbon (DLC) material on a back surface of a semiconductor substrate at a temperature between about 150° C. and about 350° C., wherein the DLC material is to protect the back surface from defects.

2. The method according to claim 1, wherein depositing the diamond-like carbon material includes having the semiconductor substrate as a wafer and depositing at a temperature up to about 350° C.

3. The method according to claim 1, wherein depositing the diamond-like carbon material includes having the semiconductor substrate as a die mounted on a package substrate and depositing at a temperature between about 150° C. to about 260° C.

4. The method according to claim 1, further comprising: singulating the semiconductor substrate.

5. The method according to claim 1, wherein depositing the diamond-like carbon material includes depositing by ion beam sputter deposition (IBSD).

6. The method according to claim 1, wherein depositing the DLC material includes depositing the DLC material at a thickness of about 25 Angstroms.

7. The method according to claim 1, wherein depositing the DLC material includes depositing the DLC material having a friction coefficient of about 0.1.

8. The method according to claim 1, wherein depositing the DLC material includes depositing the DLC material having a Vickers hardness number of between about 1000 HV and about 3000 HV.

9. The method according to claim 1, wherein depositing the DLC material includes depositing the DLC material having a thermal conductivity of between about 700 W/mK and about 1100 W/mK.

10. The method according to claim 1, wherein depositing the DLC material includes depositing the DLC material having an electrical resistivity of between about 10⁶ Ωcm and about 10¹² Ω/cm.

11-15. (canceled)

16. The method according to claim 5, wherein depositing includes rotating a sputtering target to form multiple DLC films on the back surface of the semiconductor substrate.

17. The method according to claim 5, wherein depositing includes using a sputtering target and changing position of the back surface of the semiconductor substrate to ensure more uniform deposition.

18. The method according to claim 5, wherein depositing includes directing a first beam at a sputtering target and a second beam of a noble or reactive ions at the back surface of the semiconductor substrate.

19. The method according to claim 1, wherein depositing the diamond-like carbon material includes depositing by plasma-assisted chemical vapour deposition (PACVD).

20. A method comprising:
sputter depositing a diamond-like carbon (DLC) material on a back surface of a semiconductor substrate at a temperature between about 150° C. and about 350° C., wherein depositing the DLC material includes forming a DLC film having a thickness a thickness of about 25 Angstroms, a friction coefficient of about 0.1, a Vickers hardness number of between about 1000 HV and about 3000 HV, a thermal conductivity of between about 700 W/mK and about 1100 W/mK, and an electrical resistivity of between about 10⁶ Ω/cm and about 10¹² Ω/cm.

21. The method according to claim 20, wherein depositing the DLC material includes having the semiconductor substrate as a wafer and depositing at a temperature up to about 350° C.

22. The method according to claim 20, wherein depositing the DLC material includes having the semiconductor substrate as a die mounted on a package substrate and depositing at a temperature between about 150° C. to about 260° C.

23. A method comprising:
chemical vapour deposition (CVD) depositing a diamond-like carbon (DLC) material on a back surface of a semiconductor substrate at a temperature between about 150° C. and about 350° C., wherein depositing the DLC material includes forming a DLC film having a thickness a thickness of about 25 Angstroms, a friction coefficient of about 0.1, a Vickers hardness number of between about 1000 HV and about 3000 HV, a thermal conductivity of between about 700 W/mK and about 1100 W/mK, and an electrical resistivity of between about 10⁶ Ωcm and about 10¹² Ω/cm.

24. The method according to claim 23, wherein DLC material includes having the semiconductor substrate as a wafer and depositing at a temperature up to about 350° C.

25. The method according to claim 20, wherein depositing the DLC material includes having the semiconductor substrate as a die mounted on a package substrate and depositing at a temperature between about 150° C. to about 260° C.
